(19) United States
(12) Patent Application Publication
(10) Pub. No.: US 2015/0357508 A1
(43) Pub. Date: Dec. 10, 2015

(54) OXIDE MEDIA FOR GETTERING IMPURITIES FROM SILICON WAFERS

(71) Applicant: MERCK PATENT GMBH, Darmstadt (DE)

(72) Inventors: Ingo KOEHLER, Reinheim (DE); Oliver DOLL, Dietzenbach (DE); Sebastian BARTH, Darmstadt (DE)

(73) Assignee: Merck Patent GmbH, Darmstadt (DE)

(21) Appl. No.: 14/655,366

(22) PCT Filed: Dec. 18, 2013
(86) PCT No.: PCT/EP2013/003837

§ 371 Date: Jun. 25, 2015

(30) Foreign Application Priority Data
Dec. 28, 2012 (EP) 12008660.8
Dec. 10, 2013 (EP) 13005736.7

(51) Int. Cl. H01L 31/18; H01L 21/02; H01L 21/322

(52) U.S. Cl. CPC H01L 31/186; H01L 21/3221; H01L 21/02112; H01L 21/02216; H01L 21/02282; H01L 31/1804

(57) ABSTRACT

The present invention relates to a novel process for the preparation of printable, low- to high-viscosity oxide media, and to the use thereof in the production of solar cells.

The present invention relates to a novel process for the preparation of printable, low- to high-viscosity oxide media and to the use thereof in the production of solar cells, and to the products having an improved lifetime produced using these novel media.

The production of simple solar cells or solar cells which are currently represented with the greatest market share in the market comprises the essential production steps outlined below:

1. Saw-Damage Etching and Texture

A silicon wafer (monocrystalline, multicrystalline or quasi-monocrystalline, base doping p or n type) is freed from adherent saw damage by means of etching methods and “simultaneously” textured, generally in the same etching bath. Texturing is in this case taken to mean the creation of a preferentially aligned surface (nature) as a consequence of the etching step or simply the intentional, but not particularly aligned roughening of the wafer surface. As a consequence of the texturing, the surface of the wafer now acts as a diffuse reflector and thus reduces the directed reflection, which is dependent on the wavelength and on the angle of incidence, ultimately resulting in an increase in the absorbed proportion of the light incident on the surface and thus an increase in the conversion efficiency of the same cell.

The above-mentioned etch solutions for the treatment of the silicon wafers typically consist, in the case of monocrystalline wafers, of dilute potassium hydroxide solution to which isopropyl alcohol has been added as solvent. Other alcohols having a higher vapour pressure or a higher boiling point than isopropyl alcohol may also be added instead if this enables the desired etching result to be achieved. The desired etching result obtained is typically a morphology which is characterised by pyramids having a square base which are randomly arranged, or rather etched out of the original surface. The density, the height and thus the base area of the pyramids can be partly influenced by a suitable choice of the above-mentioned components of the etch solution, the etching temperature and the residence time of the wafers in the etching tank. The texturing of the monocrystalline wafers is typically carried out in the temperature range from 70-<90° C., where etching removal rates of up to 10 μm per wafer side can be achieved.

In the case of multicrystalline silicon wafers, the etch solution can consist of potassium hydroxide solution having a moderate concentration (10-15%). However, this etching technique is hardly still used in industrial practice. More frequently, an etch solution consisting of nitric acid, hydrofluoric acid and water is used. This etch solution can be modified by various additives, such as, for example, sulfuric acid, phosphoric acid, acetic acid, N-methylpyrrolidone and also surfactants, enabling, inter alia, wetting properties of the etch solution and also its etching rate to be specifically influenced. These acidic etch mixtures produce a morphology of nested etching trenches on the surface. The etching is typically carried out at temperatures in the range between 4° C. to <10° C., and the etching removal rate here is generally 4 μm to 6 μm.

Immediately after the texturing, the silicon wafers are cleaned intensively with water and treated with dilute hydrofluoric acid in order to remove the chemical oxide layer layer formed as a consequence of the preceding treatment steps and contaminants absorbed and adsorbed therein and also thereon, in preparation for the subsequent high-temperature treatment.

2. Diffusion and Doping

The wafers etched and cleaned in the preceding step (in this case p-type base doping) are treated with vapour consisting of phosphorus oxide at elevated temperatures, typically between 750° C. and <1000° C. During this operation, the wafers are exposed to a controlled atmosphere consisting of dried nitrogen, dried oxygen and phosphoryl chloride in a quartz tube in a tubular furnace. To this end, the wafers are introduced into the quartz tube at temperatures between 600 and 700° C. The gas mixture is transported through the quartz tube. During the transport of the gas mixture through the strongly warmed tube, the phosphoryl chloride decomposes to give a vapour consisting of phosphorus oxide (for example P₂O₅) and chlorine gas. The phosphorus oxide vapour precipitates, inter alia, on the wafer surfaces (coating). At the same time, the silicon surface is oxidised at these temperatures with formation of a thin oxide layer. The precipitated phosphorus oxide is embedded in this layer, causing mixed oxide of silicon dioxide and phosphorus oxide to form on the wafer surface. This mixed oxide is known as phosphosilicate glass (PSG). This PSG glass has different softening points and different diffusion constants with respect to the phosphorus oxide depending on the concentration of the phosphorus oxide present. The mixed oxide serves as diffusion source for the silicon wafer, where the phosphorus oxide diffuses in the course of the diffusion in the direction of the interface between PSG glass and silicon wafer, where it is reduced to phosphorus by reaction with the silicon on the wafer surface (silicothermally). The phosphorus formed in this way has a solubility in silicon which is orders of magnitude higher than in the glass matrix from which it has been formed and thus preferentially dissolves in the silicon owing to the very high segregation coefficient. After dissolution, the phosphorus diffuses in the silicon along the concentration gradient into the volume of the silicon. In this diffusion process, concentration gradients in the order of 105 form between typical surface concentrations of 1021 atoms/cm² and the base doping in the region of 1016 atoms/cm². The typical diffusion depth is 250 to 500 nm and is dependent on the diffusion temperature selected (for example 880° C.) and the total exposure duration (heating & coating phase & injection phase & cooling) of the wafers in the strongly warmed atmosphere. During the coating phase, a PSG layer forms which a typical menner has a layer thickness of 40 to 60 nm. The coating of the wafers with the PSG glass, during which diffusion into the volume of the silicon also already takes place, is followed by the injection phase. This can be decoupled from the coating phase, but is in practice generally coupled directly to the coating in terms of time and is therefore usually also carried out at the same temperature. The composition of the gas mixture here is adapted in such a way that the further supply of phosphoryl chloride is suppressed. During the injection, the surface of the silicon is oxidised further by the oxygen present in the gas mixture, causing a phosphorus oxide-depleted silicon dioxide layer which likewise comprises phosphorus oxide to be generated between the actual doping source, the highly phosphorus oxide-enriched PSG glass, and the silicon wafer. The growth of this layer is very much faster in relation to the mass flow of the dopant from the source (PSG glass), since the oxide growth is accelerated by the high surface doping of the wafer itself (acceleration by one to two orders of magnitude). This enables depletion or separation of the doping source to be achieved in a certain manner, permeation of which with phosphorus oxide diffusing on is influenced by the material flow, which is dependent on the temperature and thus the diffusion coefficient. In this way, the doping of the silicon can be controlled in certain limits. A typical diffusion duration consisting of coating phase and injection phase is, for example, 25 minutes. After this treatment, the tubular furnace is automatically cooled, and the wafers can be removed from the process tube at temperatures between 600° C. to 700° C.

In the case of boron doping of the wafers in the form of an n-type base doping, a different method is carried out, which will not be explained separately here. The doping in these cases is carried out, for example, with boron trichloride or boron tribromide. Depending on the choice of the composition of the gas atmosphere employed for the doping, the formation of a so-called boron skin on the wafers may be observed. This boron skin is dependent on various influencing factors: crucially the doping atmosphere, the temperature, the doping duration, the source concentration and the coupled (or linear-combined) parameters mentioned above.

In such diffusion processes, it goes without saying that the wafers used cannot contain any regions of preferred diffusion and doping (apart from those which are formed by inhomogeneous gas flows and resultant gas pockets of inhomogeneous composition) if the substrates have not previously been subjected to a corresponding pretreatment (for example structuring thereof with diffusion-inhibiting and/or -suppressing layers and materials).

For completeness, it should also be pointed out here that there are also further diffusion and doping technologies which have become established to different extents in the production of crystalline solar cells based on silicon. Thus, mention may be made of
ion implantation,
doping promoted via the gas-phase deposition of mixed oxides, such as, for example, those of PSG and BSG (borosilicate glass), by means of APCVD, PECVD, MOCVD and LPCVD processes,
(co)sputtering of mixed oxides and/or ceramic materials and hard materials (for example boron nitride),
gas-phase deposition of the last two,
purely thermal gas-phase deposition starting from solid dopant sources (for example boron oxide and boron nitride) and
liquid-phase deposition of doping liquids (inks) and pastes.

The latter are frequently used in so-called inline doping, in which the corresponding pastes and inks are applied by means of suitable methods to the wafer side to be doped. After or also even during the application, the solvents present in the compositions employed for the doping are removed by temperature and/or vacuum treatment. This leaves the actual dopant on the wafer surface. Liquid doping sources which can be employed are, for example, dilute solutions of phosphoric or boric acid, and also sol-gel-based systems or also solutions of polymeric borazil compounds. Corresponding doping pastes are characterised virtually exclusively by the use of additional thickening polymers, and comprise dopants in suitable form. The evaporation of the solvents from the above-mentioned doping media is usually followed by treatment at high temperature, during which undesired and interfering additives, but ones which are necessary for the formulation, are either “burnt” and/or pyrolysed. The removal of solvents and the burning-out may, but do not have to, take place simultaneously. The coated substrates subsequently usually pass through a flow-through furnace at temperatures between 800° C. and 1000° C., where the temperatures may be slightly increased compared with gas-phase diffusion in the tubular furnace in order to shorten the passage time. The gas atmosphere prevailing in the flow-through furnace may differ in accordance with the requirements of the doping and may consist of dry nitrogen, dry air, a mixture of dry oxygen and dry nitrogen and/or, depending on the design of the furnace to be passed through, zones of one or other of the above-mentioned gas atmospheres. Further gas mixtures are conceivable, but currently do not have major importance industrially. A characteristic of inline diffusion is that the coating and injection of the dopant can in principle take place decoupled from one another.

3. Removal of the Dopant Source and Optional Edge Insulation

The wafers present after the doping are coated on both sides with more or less glass on both sides of the surface. More or less in this case refers to modifications which can be applied during the doping process: double-sided diffusion vs. quasi-single-sided diffusion promoted by back-to-back arrangement of two wafers in one location of the process boats used. The latter variant enables predominantly single-sided doping, but does not completely suppress diffusion on the back. In both cases, it is currently state of the art to remove the glasses present after the doping from the surfaces by means of etching in dilute hydrofluoric acid. To this end, the wafers are firstly re-loaded in batches into wet-process boats and with their aid dipped into a solution of dilute hydrofluoric acid, typically 2% to 5%, and left therein until either the surface has been completely freed from the glasses, or the process cycle duration, which represents a sum parameter of the requisite etching duration and the process automation by machine, has expired. The complete removal of the glasses can be established, for example, from the complete dewetting of the silicon wafer surface by the dilute aqueous hydrofluoric acid solution. The complete removal of a PSG glass is achieved within 210 seconds at room temperature under these process conditions, for example using 2% hydrofluoric acid solution. The etching of corresponding BSG glasses is slower and requires longer process times and possibly also higher concentrations of the hydrofluoric acid used. After the etching, the wafers are rinsed with water.

On the other hand, the etching of the glasses on the wafer surfaces can also be carried out in a horizontally operating process, in which the wafers are introduced in a constant flow into an etcher in which the wafers pass horizontally through the corresponding process tanks (inline machine). In this case, the wafers are conveyed on rollers either through the process tanks and the etch solutions present therein, or the etch media are transported onto the wafer surfaces by means of roller application. The typical residence time of the wafers during etching of the PSG is about 90 seconds, and the hydrofluoric acid used is somewhat more highly concentrated than in the case of the batch process in order to compensate for the shorter residence time as a consequence of an increased etching rate. The concentration of the hydrofluoric acid is typically 5%. The tank temperature may optionally additionally be slightly increased compared with room temperature (>25° C.<50° C.).

In the process outlined last, it has become established to carry out the so-called edge insulation sequentially at the same time, giving rise to a slightly modified process flow: edge insulation→glass etching. The edge insulation is a process-engineering necessity which arises from the system-inherent characteristic of double-sided diffusion, also in the case of intentional single-sided back-to-back diffusion. A large-area parasitic p-n junction is present on the (later) back of the solar cell, which is, for process-engineering reasons, removed partially, but not completely, during the later processing. As a consequence of this, the front and back of the solar cell are short-circuited via a parasitic and residue p-n junction (tunnel contact), which reduces the conversion efficiency of the later solar cell. For removal of this junction, the wafers are passed on one side over an etch solution consisting of nitric acid and hydrofluoric acid. The etch solution may comprise, for example, sulfuric acid or phosphoric acid as secondary constituents. Alternatively, the etch solution is transported (conveyed) via rollers onto the back of the wafer. The etch removal rate typically achieved in this process is about 1 μm of silicon (including the glass layer present on the surface to be treated) at temperatures between 4° C. to 8° C. In this process, the glass layer still present on the opposite side of the wafer serves as mask, which provides a certain protection against etch encroachment on this side. This glass layer is subsequently removed with the aid of the glass etching already described.

In addition, the edge insulation can also be carried out with the aid of plasma etching processes. This plasma etching is then generally carried out before the glass etching. To this end, a plurality of wafers are stacked one on top of the other, and the outside edges are exposed to the plasma. The plasma is fed with fluorinated gases, for example tetrafluoromethane. The reactive species occurring on plasma decomposition of these gases etch the edges of the wafer. In general, the plasma etching is then followed by the glass etching.

4. Coating of the Front Side with an Antireflection Layer

After the etching of the glass and the optional edge insulation, the front side of the later solar cells is coated with an antireflection coating, which usually consists of amorphous and hydrogen-rich silicon nitride. Alternative antireflection coatings are conceivable. Possible coatings can be titanium dioxide, magnesium fluoride, tin dioxide and/or consist of corresponding stacked layers of silicon dioxide and silicon nitride. However, antireflection coatings having a different composition are also technically possible. The coating of the wafer surface with the above-mentioned silicon nitride essentially fulfils two functions: on the one hand the layer generates an electric field owing to the numerous incorporated positive charges, that can keep charge carriers in the silicon away from the surface and can considerably reduce the recombination rate of these charge carriers at the silicon surface (field-effect passivation), on the other hand this layer generates a reflection-reducing property, depending on its optical parameters, such as, for example, refractive index and layer thickness, which contributes to it being possible for more light to be coupled into the later solar cell. The two effects can increase the conversion efficiency of the solar cell. Typical properties of the layers currently used are: a layer thickness of ˜80 nm on use of exclusively the above-mentioned silicon nitride, which has a refractive index of about 2.05. The antireflection reduction is most clearly apparent in the light wavelength region of 600 nm. The directed and undirected reflection here exhibits a value of about 1% to 3% of the originally incident light (perpendicular incidence to the surface perpendicular of the silicon wafer).

The above-mentioned silicon nitride layers are currently generally deposited on the surface by means of the direct PECVD process. To this end, a plasma into which silane and ammonia are introduced is ignited an argon gas atmosphere. The silane and the ammonia are reacted in the plasma via ionic and free-radical reactions to give silicon nitride and at the same time deposited on the wafer surface. The properties of the layers can be adjusted and controlled, for example, via the individual gas flows of the reactants. The deposition of the above-mentioned silicon nitride layers can also be carried out with hydrogen as carrier gas and/or the reactants alone. Typical deposition temperatures are in the range between 300° C. to 400° C. Alternative deposition methods can be, for example, LPCVD and/or sputtering.

5. Production of the Front-Side Electrode Grid

After deposition of the antireflection layer, the front-side electrode is defined on the wafer surface coated with silicon nitride. In industrial practice, it has become established to produce the electrode with the aid of the screen-printing method using metallic sinter pastes. However, this is only one of many different possibilities for the production of the desired metal contacts.

In screen-printing metallisation, a paste which is highly enriched with silver particles (silver content≧80%) is generally used. The sum of the remaining constituents arises from the rheological assistants necessary for formulation of the paste, such as, for example, solvents, binders and thickeners. Furthermore, the silver paste comprises a special glass-frit mixture, usually oxides and mixed oxides based on silicon dioxide, borosilicate glass and also lead oxide and/or bismuth oxide. The glass frit essentially fulfils two functions: it serves on the one hand as adhesion promoter between the wafer surface and the mass of the silver particles to be sintered, on the other hand it is responsible for penetration of the silicon nitride top layer in order to facilitate direct ohmic contact with the underlying silicon. The penetration of the silicon nitride takes place via an etching process with subsequent diffusion of silver dissolved in the glass-frit matrix into the silicon surface, whereby the ohmic contact formation is achieved. In practice, the silver paste is deposited on the wafer surface by means of screen printing and subsequently dried at temperatures of about 200° C. to 300° C. for a few minutes. For completeness, it should be mentioned that double-printing processes are also used industrially, which enable a second electrode grid to be printed with accurate registration onto an electrode grid generated during the first printing step. The thickness of the silver metallisation is thus increased, which can have a positive influence on the conductivity in the electrode grid. During this drying, the solvents present in the paste are expelled from the paste. The printed wafer subsequently passes through a flow-through furnace. A furnace of this type generally has a plurality of heating zones which can be activated and temperature-controlled independently of one another. During passivation of the flow-through furnace, the wafers are heated to temperatures up to about 950° C. However, the individual wafer is generally only subjected to this peak temperature for a few seconds. During the remainder of the flow-through phase, the wafer has temperatures of 600° C. to 800° C. At these temperatures, organic accompanying substances present in the silver paste, such as, for example, binders, are burnt out, and the etching of the silicon nitride layer is initiated. During the short time interval of prevailing peak temperatures, the contact formation with the silicon takes place. The wafers are subsequently allowed to cool.

The contact formation process outlined briefly in this way is usually carried out simultaneously with the two remaining contact formations (cf. 6 and 7), which is why the term co-firing process is also used in this case.

The front-side electrode grid consists per se of thin fingers (typical number>=68) which have a width of typically 80 μm to 140 μm, and also busbars having widths in the range from 1.2 mm to 2.2 mm (depending on their number, typically two to three). The typical height of the printed silver elements is generally between 10 μm and 25 μm. The aspect ratio is rarely greater than 0.3.

6. Production of the Back Busbars

The back busbars are generally likewise applied and defined by means of screen-printing processes. To this end, a similar silver paste to that used for the front-side metallisation is used. This paste has a similar composition, but comprises an alloy of silver and aluminium in which the proportion of aluminium typically makes up 2%. In addition, this paste comprises a lower glass-frit content. The busbars, generally two units, are printed onto the back of the wafer by means of screen printing with a typical width of 4 mm and compacted and are sintered as already described under point 5.

7. Production of the Back Electrode

The back electrode is defined after the printing of the busbars. The electrode material consists of aluminium, which is why an aluminium-containing paste is printed onto the remaining free area of the wafer back by means of screen printing with an edge separation<1 mm for definition of the electrode. The paste is composed of up to 80% of aluminium. The remaining components are those which have already been mentioned under point 5 (such as, for example, solvents, binders, etc.). The aluminium paste is bonded to the wafer during the co-firing by the aluminium particles beginning to melt during the warming and silicon from the wafer dissolving in the molten aluminium. The melt mixture functions as dopant source and releases aluminium to the silicon (solubility limit: 0.016 atom percent), where the silicon is p⁺-doped as a consequence of this injection. During cooling of the wafer, a eutectic mixture of aluminium and silicon, which solidifies at 577° C. and has a composition having a mole fraction of 0.12 of Si, deposits, inter alia, on the wafer surface.

As a consequence of the injection of aluminium into the silicon, a highly doped p-type layer, which functions as a type of mirror (“electric mirror”) on parts of the free charge carriers in the silicon, forms on the back of the wafer. These charge carriers cannot overcome this potential wall and are thus kept away from the back wafer surface very efficiently, which is thus evident from an overall reduced recombination rate of charge carriers at this surface. This potential wall is generally referred to as back surface field.

The sequence of the process steps described under points 5, 6 and 7 can, but does not have to, correspond to the sequence outlined here. It is evident to the person skilled in the art that the sequence of the outlined process steps can in principle be carried out in any conceivable combination.

8. Optional Edge Insulation

If the edge insulation of the wafer has not already been carried out as described under point 3, this is typically carried out with the aid of laser-beam methods after the co-firing. To this end, a laser beam is directed at the front of the solar cell, and the front-side p-n junction is parted with the aid of the energy coupled in by this beam. Cut trenches having a depth of up to 15 μm are generated here as a consequence of the action of the laser. At the same time, silicon is removed from the treated site via an ablation mechanism or thrown out of the laser trench. This laser trench typically has a width of 30 μm to 60 μm and is about 200 μm away from the edge of the solar cell.

After production, the solar cells are characterised and classified in individual performance categories in accordance with their individual performances.

The person skilled in the art is aware of solar-cell architectures with both n-type and also p-type base material. These solar cell types include:
PERC solar cells
PERL solar cells
PERT solar cells
MWT-PERT and MWT-PERL solar cells derived therefrom
bifacial solar cells
back surface contact cells
back surface contact cells with interdigital contacts.

The choice of alternative doping technologies, as an alternative to the gas-phase doping already described at the outset, generally cannot solve the problem of the production of regions with locally different doping on the silicon substrate. Alternative technologies which may be mentioned here are the deposition of doped glasses, or of amorphous mixed oxides, by means of PECVD and APCVD processes. Thermally induced doping of the silicon located under these glasses can easily be achieved from these glasses. However, in order to produce regions with locally different doping, these glasses must be etched by means of mask processes in order to prepare the corresponding structures out of these. Alternatively, structured diffusion barriers can be deposited on the silicon wafers prior to the deposition of the glasses in order thus to define the regions to be doped. However, it is disadvantageous in this process that in each case only one polarity (n or p) of the doping can be achieved. Somewhat simpler than the structuring of the doping sources or of any diffusion barriers is direct laser beam-supported injection of dopants from dopant sources deposited in advance on the wafer surfaces. This process enables expensive structuring steps to be saved. However, it cannot compensate for the disadvantage of possibly desired simultaneous doping of two polarities on the same surface at the same time (co-diffusion), since this process is likewise based on pre-deposition of a dopant source which is only activated subsequently for the release of the dopant. A disadvantage of this (post)doping from such sources is the unavoidable laser damage of the substrate: the laser beam must be converted into heat by absorption of the radiation. Since the conventional dopant sources consist of mixed oxides of silicon and the dopants to be injected, i.e. of boron oxide in the case of boron, the optical properties of these mixed oxides are consequently fairly similar to those of silicon oxide. These glasses (mixed oxides) therefore have a very low coefficient for radiation in the relevant wavelength range. For this absorption reason, the silicon located under the optically transparent glasses is used as absorption source. The silicon is in some cases heated here until it melts, and consequently warms the glass located above it. It facilitates diffusion of the dopants—and does so a multiple faster than would be expected at normal diffusion temperatures, so that a very short diffusion time for the silicon arises (less than 1 second). The silicon is intended to cool again relatively quickly after absorption of the laser radiation as a consequence of the strong transport of the heat away into the remaining, non-irradiated volume of the silicon and at the same time solidify epitactically on the non-molten material. However, the overall process is in reality accompanied by the formation of laser radiation-induced defects, which may be attributable to incomplete epitactic solidification and thus the formation of crystal defects. This can be attributed, for example, to dislocations and formation of vacancies and flaws as a consequence of the shock-like progress of the process. A further disadvantage of laser beam-supported diffusion is the relative inefficiency if relatively large areas are to be doped quickly, since the laser system scans the surface in a dot-grid process. This disadvantage naturally has less weight in the case of narrow regions to be doped. However, laser doping requires sequential deposition of the post-treatable glasses.

A fundamental problem in the production of solar cells is, in addition, the requisite high purity of the silicon wafers originally employed, since this is a basic prerequisite for the functional capability and effectiveness of the cells produced. In order to achieve the requisite purity, it is generally necessary to carry out complex and expensive cleaning processes.

In order to reduce the costs for crystalline silicon solar cells, it is desirable to be able to employ inexpensive “upgraded metallurgical grade” (UMG) silicon in the photovoltaics industry. Conventional high-purity silicon is prepared with the aid of complex processes, based on the so-called Siemens process. This utilises the reaction to give chlorosilanes, which are subsequently distilled a number of times and deposited on thin high-purity silicon rods. By contrast, UMG silicon is obtained from crude silicon via physical-chemical purification (for example acid extraction and/or segregation). However, this silicon contains much higher contaminant concentrations, especially 3d transition metals, such as, for example, Ti, Fe, Cu. These metals are extremely harmful in the electrically active part of solar cells since they form charge-carrier recombination centres in the band gap of silicon.

The aim is therefore to remove interfering contaminants from inexpensive silicon carrier materials between or during the cell-process steps by simple cleaning methods, such as so-called gettering.

In general, gettering is a process in which contaminants are removed or moved to where they are less harmful for the solar cell. In general, this step is carried out by so-called HCl gettering. This is a process which is based on the reaction of gaseous hydrogen chloride (HCl) with metals and the formation of metal chlorides which are volatile at high temperatures. Although this process removes the interfering contaminants, it is, however, necessary to provide particular safety measures in order to prevent escape of HCl gases from the plant. In addition, the HCl gases are corrosive for the plant, meaning that it is desirable to be able to carry out the removal of the contaminants while avoiding an etching gas atmosphere, preferably in combination with another process step.

### Object of the Present Invention

As is evident from the above description, the industrial production of crystalline silicon solar cells makes high demands of the purity of the chemicals and assistants used therein. These purity demands will become even greater in the future, since the further increase in the efficiency of solar cells which is aimed at is inevitably associated with an increase in the of the maximum-operating-point voltage corresponding to the cell. The voltage of the cell can be increased by various methods. Various solutions on this topic have been described in the literature. These include, inter alia, the following solution approaches: the concept of the selective emitter, the concept of the local back surface field, the concept of the back surface contact cell with p/n junctions placed on the back, and others. Starting from a simplified consideration of the action of solar cells, both the current yield and also the voltage of the solar cells must be increased. However, the two solar-cell parameters are mutually dependent quantities. The current yield, the short-circuit current I_{SC}, can no longer be increased significantly or disproportionally without further means, since it is dependent on the light intensity coupled into or absorbed by the solar cell—if the incident light intensity is not concentrated.

The usual methods, such as the use of special surface textures, antireflection layers, etc., are already employed in all solar-cell architectures, meaning that the internal quantum yield remains as the crucial factor which has an essential influence for the yield of the short-circuit current:

$$\begin{matrix}η = \frac{{I}_{m} {V}_{m}}{{P}_{light}} = \frac{{FFI}_{sc} {V}_{oc}}{{P}_{light}} & ( I ) \\ {V}_{oc} \approx {U}_{T} ln ( {I}_{sc} / {I}_{o} ) & ( II )\end{matrix}$$

It is apparent from equation (II) that the maximum achievable open-circuit voltage (V_{OC}) of the solar cell are essentially dependent on the short-circuit current density and the dark-current saturation density (Iₒ).

As described in a simplified manner above, the short-circuit current density cannot simply be increased as desired—the solar spectrum (AM1.5 in accordance with IEC 60904-3 Ed. 2) produces an integrated light intensity of 804.6 W/m² in the wavelength range between 280 nm and 1100 nm, which corresponds to 43.5 mA/cm²—so that a possible optimisation parameter could be the dark-current saturation density. A maximum increase in voltage of 17-18 mV can usually be expected as a consequence of the halving of the dark-current saturation density at a short-circuit current density assumed to be constant. This is composed of the proportions of the emitter and the wafer base. The above-mentioned novel solar-cell concepts essentially address, inter alia, the increase in the voltage of the solar cell by advantageously influencing the dark-current saturation density: the concept of the selective emitter optimises the proportion of the emitter in the dark-current saturation density, and the concept of the local back surface field addresses the inflowing proportion of the base. However, the dark-current saturation density is not dependent exclusively on the effects occurring as a consequence of modifications on the wafer surface in the course of technological implementation of the two concepts mentioned, but also cannot be attributed exclusively to the advantages thereof which arise essentially through the drastic reduction in the surface recombination rates of the excess charge carriers produced. The charge-carrier lifetime in the volume of the silicon plays just as important a role and is an essential key parameter for the solar cell. The charge-carrier lifetime is dependent on many factors and accordingly can also easily be manipulated. Without wishing to mention these factors individually, the “material quality” is frequently mentioned in this connection. A long-known and frequently discussed cause by which the material quality of the silicon is adversely affected is the injection of contaminants into the volume of the crystal. Such contaminants are typically elements of the transition metals, such as, for example, iron, copper and nickel, which can considerably reduce the lifetimes of charge carriers (>three orders of magnitude, correspondingly from milliseconds to microseconds or less). Thus, for example, gold is specifically used for the production of certain integrated circuits in order to reduce the response times of the component. 3d transition metals now occur in virtually every production environment of solar cells, and some of these representatives, such as, for example, iron, are ubiquitous, for example can be found in all common chemicals. Since even the tiniest traces (ratio 1:10⁶-10¹⁰ in atoms/cm³) may be sufficient to permanently damage silicon wafers electronically, in particular after processing thereof after a high-temperature phase, the avoidance of contamination or the “healing” thereof has particular importance in the production of semiconductor components based on silicon.

The object of the present invention is therefore to provide a simple process which is inexpensive to carry out, and a medium which can be employed in this process, by means of which this damaging contamination can be suppressed or eliminated (healed).

Subject-Matter of the Invention

The present invention provides a process for the production of a handling- and abrasion-resistant layer having a gettering effect on silicon wafers,

by means of which a getter medium in the form of an oxide medium is printed onto the surface of silicon wafers,

which medium has been prepared by

condensation and controlled gelling of symmetrically and/or asymmetrically di- to tetrasubstituted alkoxysilanes and alkoxyalkylsilanes with
a. symmetrical and asymmetrical organic and mixed organic/inorganic carboxylic anhydrides
   or with
b. strong carboxylic acids,
   and with simultaneous use of typical substances which have a doping action on silicon, i.e. advantageously influence its conductivity, and the printed-on medium is dried and compacted for vitrification in a temperature range between 50° C. and 800° C., preferably between 50° C. and 500° C., by means of one or more heating steps to be carried out sequentially (heating by means of a step function) and/or a heating ramp, and the temperature, optionally after increasing, is subsequently kept in a range from 500 to 800° C., preferably in a range from 600 to 750° C., for a few seconds to one minute, resulting in the formation of a handling- and abrasion-resistant layer having a thickness of up to 500 nm.

During the vitrification of the printed oxide medium, after drying and compaction thereof, without inducing intentional doping of the substrate itself, and the treatment at elevated temperature, a gettering effect is simultaneously produced, causing the removal of undesired contaminants from the underlying layer, the silicon, advantageously by diffusion, and improving the lifetimes of the minority charge carriers.

The oxide medium in high-viscosity form is preferably printed onto silicon wafers and, besides the getter action after thermal compaction and vitrification thereof, produces an effect as diffusion barrier against phosphorus and boron diffusion.

If desired, however, getter media which are prepared using boron-containing compounds selected from the group boron oxide, boric acid and boric acid esters and/or phosphorus-containing compounds selected from the group phosphorus(V) oxide, phosphoric acid, polyphosphoric acid, phosphoric acid esters and phosphoric acid esters containing siloxane-functionalised groups in the alpha- and/or beta-position can be used in the process according to the invention.

In this case, the vitrified layers on the surfaces can release silicon-doping atoms, such as boron and/or phosphorus, to the substrate by temperature treatment at a temperature in the range between 750° C. and 1100° C., preferably between 850° C. and 1100° C., influencing the conductivity of the substrate. The temperature treatment at these high temperatures transports the dopants to depths of up to 1 μm and produces electrical sheet resistivities of up to 10 Ω/sqr, where surface concentrations of the dopant of greater than or equal to 1*10²¹ atoms/cm³ are obtained. At the same time, a state is thereby generated in which the concentration of parasitic doping on the treated substrates differs by at least two powers of ten from the doping of intentionally doped regions.

The getter medium can advantageously be printed onto hydrophilic and/or hydrophobic silicon wafer surfaces. In addition, it has proven favourable, after the printing of the getter media according to the invention, drying, compaction and vitrification thereof and optionally doping by suitable temperature treatment, for the glass layers formed to be etched with an acid mixture comprising hydrofluoric acid and optionally phosphoric acid and thus for hydrophobic silicon wafer surfaces to be obtained. Etch mixtures which are suitable for this purpose comprise, as etchant, hydrofluoric acid in a concentration of 0.001 to 10% by weight. However, they may also comprise 0.001 to 10% by weight of hydrofluoric acid and 0.001 to 10% by weight of phosphoric acid in a mixture.

The getter media used in the process are prepared using symmetrically and/or asymmetrically di- to tetrasubstituted alkoxysilanes and alkoxyalkylsilanes which contain saturated or unsaturated, branched or unbranched, aliphatic, alicyclic or aromatic radicals, individually or various of these radicals, which may in turn be functionalised at any desired position of the alkoxide radical or alkyl radical by heteroatoms selected from the group O, N, S, Cl, Br. These alkoxysilanes and alkoxyalkylsilanes are converted into the desired getter media by condensation and controlled gelling with strong carboxylic acids from the group formic acid, acetic acid, oxalic acid, trifluoroacetic acid, mono-, di- and trichloroacetic acid, glyoxalic acid, tartaric acid, maleic acid, malonic acid, pyruvic acid, malic acid, 2-oxoglutaric acid. In particular, printable getter media based on hybrid sols and/or gels are obtained if alcoholates/esters, acetates, hydroxides or oxides of aluminium, germanium, zinc, tin, titanium, zirconium or lead, or mixtures thereof, are used in the condensation reaction. For this purpose, the getter medium is preferably gelled to give a high-viscosity, approximately glass-like material, and the product obtained is either re-dissolved by addition of a suitable solvent or solvent mixture or transformed into a sol state with the aid of high-shear mixing devices and converted into a homogeneous gel by partial or complete structure recovery (gelling). In order to improve the stability, it has proven advantageous for to the “capping agents” selected from the group acetoxytrialkylsilanes, alkoxytrialkylsilanes, halotrialkylsilanes and derivatives thereof to be added individually or in a mixture. It is particularly advantageous in this connection that the getter medium is formulated as high-viscosity oxide medium without addition of thickeners. In accordance with the invention, the high-viscosity getter medium can be printed in the claimed process by spin or dip coating, drop casting, curtain or slot-dye coating, screen or flexographic printing, gravure, ink-jet or aerosol-jet printing, offset printing, microcontact printing, electrohydrodynamic dispensing, roller or spray coating, ultrasonic spray coating, pipe jetting, laser transfer printing, pad printing or rotary screen printing, but preferably by means of screen printing.

The present invention thus also relates, in particular, to a getter medium in the form of a printable oxide medium which comprises binary or ternary systems from the group SiO₂—Al₂O₃ and/or mixtures of higher order which arise through the use of alcoholates/esters, acetates, hydroxides or oxides of aluminium, germanium, zinc, tin, titanium, zirconium or lead during the preparation.

This getter medium is advantageously stable on storage at least for a time of three months and can be used for the production of diffusion barriers in treatment processes of silicon wafers for photovoltaic, microelectronic, micromechanical and micro-optical applications or for the production of diffusion barriers in treatment processes of silicon wafers for photovoltaic, microelectronic, micromechanical and micro-optical applications, or also for the production of PERC, PERL, PERT, IBC solar cells and others, where the solar cells have further architecture features, such as MWT, EWT, selective emitter, selective front surface field, selective back surface field and bifaciality. Furthermore, it can be employed for the production of thin, dense glass layers which act as sodium and potassium diffusion barrier in LCD technology as a consequence of thermal treatment or for the production of thin, dense glass layers on the cover glass of a display, consisting of doped SiO₂, which prevent the diffusion of ions from the cover glass into the liquid-crystalline phase.

### DETAILED DESCRIPTION OF THE INVENTION

Surprisingly, it has now been found that the use of suitably formulated doping inks or pastes, also called getter media or pastes below, in a suitable process for extrinsic gettering advantageously enables the material quality of contaminated silicon wafers to be improved, and that the lifetime of the minority charge carriers can thus be extended. The gettering of the silicon wafers can preferably be carried out after diffusion thereof with the above-mentioned doping media at temperatures below the usual diffusion temperatures if the diffusivity of the dopants, for example into silicon, are sufficiently low. The gettering here is preferably carried out in a variable plateau time after the diffusion as part of the diffusion process.

In particular, it has been found that the problems described above can be solved by the use of printable, low- to high-viscosity oxide media as getter media which can be prepared in an anhydrous sol-gel-based synthesis, to be precise by condensation of symmetrically and/or asymmetrically di- to tetrasubstituted alkoxysilanes and alkoxyalkylsilanes with

a) symmetrical and asymmetrical (organic and inorganic) carboxylic anhydrides

or with

b) strong carboxylic acids

c) with combination of variants a) and b)

and by controlled gelling to give low- to high-viscosity oxide media.

Particularly good process results are achieved if low-viscosity or paste-form high-viscosity oxide media are prepared, to be precise in an anhydrous sol-gel-based synthesis by condensation of symmetrically and/or asymmetrically di- to tetrasubstituted alkoxysilanes and alkoxyalkylsilanes with

a) symmetrical and asymmetrical (organic and inorganic) carboxylic anhydrides
i. in the presence of boron-containing compounds
   and/or
ii. in the presence of phosphorus-containing compounds

or

b) with strong carboxylic acids
iii. in the presence of boron-containing compounds
   and/or
iv. in the presence of phosphorus-containing compounds

or

c) with combination of variants a) and b)
v. in the presence of boron-containing compounds
   and/or
vi. in the presence of phosphorus-containing compounds

and by controlled gelling.

For the preparation of the described oxide media according to the invention, the alkoxysilanes and alkoxyalkylsilanes used may contain individual or different saturated or unsaturated, branched or unbranched, aliphatic, alicyclic or aromatic radicals, which may in turn be functionalised at any desired position of the alkoxide radical by heteroatoms selected from the group O, N, S, Cl and Br. Boron-containing media are preferably prepared using compounds selected from the group boron oxide, boric acid and boric acid esters.

If phosphorus-containing compounds are used in accordance with the invention, oxide media having good properties are obtained if the phosphorus-containing compounds are selected from the group phosphorus(V) oxide, phosphoric acid, polyphosphoric acid, phosphoric acid esters and phosphonic acid esters containing siloxane-functionalised groups in the alpha- and beta-position.

The condensation reaction can, as stated above, be carried out in the presence of strong carboxylic acids.

Carboxylic acids are taken to mean organic acids of the general formula

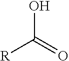

in which the chemical and physical properties are clearly determined by the carboxyl group, since the carbonyl group (C═O) has a relatively strong electron-withdrawing effect, so that the bond of the proton in the hydroxyl group is strongly polarised, which can result in easy release thereof with liberation of H⁺ ions in the presence of a basic compound. The acidity of the carboxylic acids is higher if a substituent having an electron-withdrawing (−I effect) is present on the alpha-C atom, such as, for example, in corresponding halogenated acids or in dicarboxylic acids. Accordingly, strong carboxylic acids which are particularly suitable for use in the process according to the invention are acids from the group formic acid, acetic acid, oxalic acid, trifluoroacetic acid, mono-, di- and trichloroacetic acid, glyoxalic acid, tartaric acid, maleic acid, malonic acid, pyruvic acid, malic acid, 2-oxoglutaric acid.

The process described enables the printable oxide media to be prepared in the form of doping media based on hybrid sols and/or gels using alcoholates or esters, acetates, hydroxides or oxides of aluminium, germanium, zinc, tin, titanium, zirconium or lead, and mixtures thereof. Addition of suitable masking agents, complexing agents and chelating agents in a sub- to fully stoichiometric ratio enables these hybrid sols on the one hand to be sterically stabilised and on the other hand specifically influenced and controlled with respect to their condensation and gelling rate, but also with respect to the rheological properties. Suitable masking agents and complexing agents as well as chelating agents are known to the person skilled in the art from the patent applications WO 2012/119686 A, WO2012119685 A1 and WO2012119684 A. The contents of these specifications are therefore incorporated into the disclosure content of the present application by way of reference.

In accordance with the invention, the oxide medium can be gelled to give a high-viscosity, approximately glass-like material, and the resultant product is either re-dissolved by addition of a suitable solvent or solvent mixture or transformed into a sol state with the aid of high-shear mixing devices and allowed to recover to give a homogeneous gel by partial or complete structure recovery (gelling).

It has proven particularly advantageous that the high-viscosity oxide media are formulated without addition of thickeners. In this way, stable oxide media in the form of inks or pastes are obtained in accordance with the invention as getter media which are stable on storage for a time of at least three months.

If “capping agents” selected from the group acetoxytrialkylsilanes, alkoxytrialkylsilanes, halotrialkylsilanes and derivatives thereof are added to the oxide media during the preparation, this results in an improvement in the stability of the media obtained. In the case of the preparation of low-viscosity oxide media, the addition of capping agents produces a significant increase in the storage stability. The added “capping agents” need not necessarily be incorporated into the condensation and gelling reaction, but instead their time of addition may also be selected so that they can be stirred into the resultant paste material after gelling is complete, where the capping agent reacts chemically with reactive end groups, such as, for example, silanol groups, present in the network and thus prevents them from undergoing further condensation events which occur in an uncontrolled and undesired manner.

The oxide media prepared in accordance with the invention can, depending on the consistency, be printed by spin or dip coating, drop casting, curtain or slot-dye coating, screen or flexographic printing, gravure, ink-jet or aerosol-jet printing, offset printing, microcontact printing, electrohydrodynamic dispensing, roller or spray coating, ultrasonic spray coating, pipe jetting, laser transfer printing, pad printing or rotary screen printing.

Correspondingly prepared oxide media are particularly suitable for the production of PERC, PERL, PERT, IBC solar cells and others, where the solar cells have further architecture features, such as MWT, EWT, selective emitter, selective front surface field, selective back surface field and bifaciality, or for the production of thin, dense glass layers which act as sodium and potassium diffusion barrier in LCD technology as a consequence of thermal treatment, in particular for the production of thin, dense glass layers on the cover glass of a display, consisting of doped SiO₂, which prevent the diffusion of ions from the cover glass into the liquid-crystalline phase.

The present invention accordingly also relates to the novel oxide media prepared in accordance with the invention which have been prepared by the process described above and which comprise binary or ternary systems from the group SiO₂—P₂O₅, SiO₂—B₂O₃ and SiO₂—P₂O₅—B₂O₃ and SiO₂—Al₂O₃—B₂O₃ and/or mixtures of higher order which arise through the use of alcoholates or esters, acetates, hydroxides or oxides of aluminium, germanium, zinc, tin, titanium, zirconium or lead during preparation. As already stated above, addition of suitable masking agents, complexing agents and chelating agents in a sub- to fully stoichiometric ratio enables these hybrid sols on the one hand to be sterically stabilised and on the other hand to be specifically influenced and controlled with respect to their condensation and gelling rate, but also with respect to the rheological properties. Masking agents and complexing agents as well as chelating agents which are suitable for this purpose are known to the person skilled in the art from the patent applications WO 2012/119686 A, WO2012119685 A1 and WO2012119684 A.

The oxide media obtained in this way enable a handling- and abrasion-resistant layer to be produced on silicon wafers. This can be carried out in a process in which the oxide medium prepared by a process in accordance with the invention and printed on the surface is dried and compacted for vitrification in a temperature range between 50° C. and 750° C., preferably between 50° C. and 500° C., particularly preferably between 50° C. and 400° C., by means of one or more heating steps to be carried out sequentially (heating by means of a step function) and/or a heating ramp, forming a handling- and abrasion-resistant layer having a thickness of up to 500 nm.

The glass layers obtained after drying and compaction of the oxide media according to the invention and also after the possible doping of silicon wafers with the aid of above-mentioned can be etched with an acid mixture comprising hydrofluoric acid and optionally phosphoric acid in a residue-free manner to give hydrophobic silicon surfaces, where the etch mixture used may comprise, as etchant, hydrofluoric acid in a concentration of 0.001 to 10% by weight or 0.001 to 10% by weight of hydrofluoric acid and 0.001 to 10% by weight of phosphoric acid in a mixture. The dried and compacted doping glasses can furthermore be removed from the wafer surface using etch mixtures. The etch mixtures can be compositions such as buffered hydrofluoric acid mixtures (BHF), buffered oxide etch mixtures, etch mixtures consisting of hydrofluoric and nitric acid, such as, for example, so-called P etches, R etches, S etches, or etch mixtures comprising hydrofluoric and sulfuric acid, where this list makes no claim to completeness.

The desired and advantageous gettering effect of the layer produced is obtained after treatment at elevated temperature in the range between 500° C. and 800° C., particularly preferably between 600° C. and 750° C., with and without diffusion (getter diffusion).

The oxide media printed onto the silicon wafer surfaces advantageously exert, after drying and compaction, a gettering effect on the printed silicon without doping of the substrate and at the same time have a positive influence on the lifetimes of the minority charge carriers.

Surprisingly, the printable, viscous oxide media according to the invention prepared by a sol-gel process and hereby made available can solve the problems described at the outset. For the purposes of the present invention, these oxide media can also be formulated as printable doping media by means of suitable additives. This also means that these novel oxide media can be synthesised on the basis of the sol-gel process and, if necessary, are formulated further.

The synthesis of the sol and/or gel can be controlled specifically by addition of condensation initiators, such as, for example, a carboxylic anhydride and/or a strong carboxylic acid, with exclusion of water. The viscosity can thus be controlled via the stoichiometry of the addition, for example of the acid anhydride. The degree of crosslinking of the silica particles can be adjusted by a superstoichiometric addition, enabling the formation of a highly swollen network. In the case of a relatively low degree of crosslinking, the resultant ink has low viscosity and is printable and can be applied to surfaces, preferably to silicon wafer surfaces, by means of various printing processes.

Suitable printing processes may be the following:

spin or dip coating, drop casting, curtain or slot-dye coating, screen or flexographic printing, gravure or ink-jet or aerosol-jet printing, offset printing, microcontact printing, electrohydrodynamic dispensing, roller or spray coating, ultrasonic spray coating, pipe jetting, laser transfer printing, pad printing, screen printing and rotary screen printing.

This list is not definitive, and other printing processes may also be suitable.

Furthermore, the properties of the getter materials according to the invention can be adjusted more specifically by addition of further additives, making them ideally suited for specific printing processes and for application to certain surfaces with which they may interact intensely. In this way, properties such as, for example, surface tension, viscosity, wetting behaviour, drying behaviour and adhesion capacity can be set specifically. Depending on the requirements of the getter materials prepared, further additives may also be added. These may be:
surfactants, tensioactive compounds for influencing the wetting and drying behaviour,
antifoams and deaerating agents for influencing the drying behaviour,
further high- and low-boiling polar protic and aprotic solvents for influencing the particle-size distribution, the degree of precondensation, the condensation, wetting and drying behaviour as well as the printing behaviour,
further high- and low-boiling nonpolar solvents for influencing the particle-size distribution, the degree of precondensation, the condensation, wetting and drying behaviour and the printing behaviour,
particulate additives for influencing the rheological properties,
particulate additives (for example aluminium hydroxides and aluminium oxides, silicon dioxide) for influencing the dry-film thicknesses resulting after drying as well as the morphology thereof,
particulate additives (for example aluminium hydroxides and aluminium oxides, silicon dioxide) for influencing the scratch resistance of the dried films,
oxides, hydroxides, basic oxides, alkoxides, precondensed alkoxides of boron, gallium, silicon, germanium, zinc, tin, phosphorus, titanium, zirconium, yttrium, nickel, cobalt, iron, cerium, niobium, arsenic, lead and others for the formulation of hybrid sols,
in particular simple and polymeric oxides, hydroxides, alkoxides of boron and phosphorus for the formulation of formulations which have a doping action on semiconductors, in particular silicon.

In this connection, it goes without saying that each print-coating method makes its own requirements of the ink to be printed and/or the paste resulting from the ink. Parameters to be set individually for the respective printing method are typically those such as the surface tension, the viscosity and the total vapour pressure of the ink or the paste arising therefrom.

Besides their use as getter materials, the printable media can be used as scratch-protection and corrosion-protection layers, for example in the production of components in the metal industry, preferably in the electronics industry, and here in particular in the manufacture of microelectronic, photovoltaic and microelectromechanical (MEMS) components. Photovoltaic components in this connection are taken to mean, in particular, solar cells and modules. Furthermore, applications in the electronics industry are characterised by the use of the said inks and pastes in the following areas, which are mentioned by way of example, but are not comprehensive: manufacture of thin-film solar cells from thin-film solar modules, production of organic solar cells, production of printed circuits and organic electronics, production of display elements based on the technologies of thin-film transistors (TFTs), liquid crystals (LCDs), organic light-emitting diodes (OLEDs) and touch-sensitive capacitive and resistive sensors.

The application according to the invention of the inks or pastes ideally forms a thin homogeneous film or layer on the silicon surfaces, which forms a smooth surface even after drying and compaction. On very rough surfaces, such as those of textured silicon wafer surfaces, this is more demanding, and an adapted application method has to be used.

Suitable getter media which can also be applied in a simple manner to demanding surfaces and can advantageously be inserted in the production process have to meet various requirements. In particular, the purity of the starting substances represents a problem in materials known to date for this purpose.

In general, the assistants necessary for paste formulation and here particularly the polymeric binders represent a source of contamination which is difficult to control and has an adverse effect on the performance of the silicon wafer and its lifetime.

The binders usually added for the formulation of pastes are generally extremely difficult or even impossible to purify chemically or to free from their freight of metallic trace elements. The effort for their purification is high and, owing to the high costs, represents a problem in the context of a competitive production process. These assistants thus represent a constant contamination source by means of which undesired contamination in the form of on metallic species is strongly favoured.

Further disadvantages arise in the case of extended storage durations of the media in the course of application. Extended storage results, for example, in agglutination thereof or rapid partial drying (out) thereof on the screen-printing screen, which makes complex removal of the residues necessary after thermal treatment of the wafers. Since contamination generally limits the carrier lifetime, even that adhering to the wafer surface results in a reduction thereof by drastically increasing the recombination rate at the wafer surface.

Surprisingly, these problems can be solved by the present invention, more precisely by printable, viscous oxide media according to the invention, which can be prepared by a sol-gel process. In the course of the present invention, these oxide media can be prepared as printable getter materials. In particular, a correspondingly adapted preparation and optimised synthesis approaches enable the preparation of printable getter materials
which have excellent storage stability,
which exhibit excellent printing performance with prevention of agglutination and clumping on the screen,
which have an extremely low intrinsic contamination freight of metallic species and thus do not adversely affect the lifetime of the treated silicon wafers,
which facilitate very homogeneous printing of the treated silicon wafers with formation of smooth surfaces,
   and
which, due to the preparation, do not comprise any conventionally known thickeners.

The present description enables the person skilled in the art to apply the invention comprehensively. Even without further comments, it is therefore assumed that a person skilled in the art will be able to utilise the above description in the broadest scope.

If there is any lack of clarity, it goes without saying that the publications and patent literature cited should be consulted. Accordingly, these documents are regarded as part of the disclosure content of the present description.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present application to these alone.

Furthermore, it goes without saying to the person skilled in the art that, both in the examples given and also in the remainder of the description, the component amounts present in the compositions always only add up to 100% by weight, mol-% or % by vol., based on the entire composition, and cannot exceed this, even if higher values could arise from the percent ranges indicated. Unless indicated otherwise, % data are therefore regarded as % by weight, mol-% or % by vol.

The temperatures given in the examples and description as well as in the claims are always in ° C.

### EXAMPLES

### Example 1

A p-type wafer polished on one side (divided into equally sized pieces) having a lifetime (measured using wet-chemical methanol/quinhydronepassivation and quasi-static photoconductivity measurement) of greater than or equal to 800 μs, measured at an injection density of 5*10¹⁴ cm⁻³, is intentionally treated with the aid of an iron-contaminated solution. To this end, 0.1 g of iron trichloride hexahydrate is dissolved in 85 g of water, 12 g of hydrogen peroxide and 1.25 g of acetic acid and warmed to 95° C. The wafer is treated in this solution for 10 minutes and left in this solution during cooling thereof for a further two hours.

The silicon surface, if provided with oxide and thus with silanol groups on the surface, is highly adsorptive for iron cations. The adsorbed iron can penetrate the thin oxide layer as a consequence of a subsequent high-temperature treatment and enter the volume of the silicon. It is known that iron can segregate at oxidic interfaces and can very easily form iron silicides at the surface of silicon. These silicides represent both a contamination source and a contamination sink. In spite of this silicide formation and the associated partial function as sink, it is not known that these can act in such a way that iron which has diffused into the volume of the silicon can be completely removed therefrom owing to the action as sink. The silicides possibly present on the surface have, even if they can act as sink, an influence on the lifetime to be observed, since surface contaminants reduces the effective lifetime of the minority charge carriers of silicon owing to the increase in the surface recombination rate. Iron is one of the contaminants which diffuse at a moderately fast rate in silicon and has, in p-type silicon, a very large trapping cross section for minority charge carriers, electrons, whose lifetime can be determined from their decay function after irradiation by means of photoconductivity measurements.

The wafer is subsequently treated in a muffle furnace at 900° C. for five minutes in order to inject the iron adsorbed at the surface into the silicon. The lifetime of the treated wafer is measured with the aid of wet-chemical methanol/quinhydrone passivation and quasi-static photoconductivity measurement) and read off at an injection density of 5*10¹⁴ cm⁻³. The lifetime is 3 μs and is thus a factor of ˜170 shorter compared with the starting position.

After this treatment, the wafer pieces are coated on both sides with getter medium according to Examples 2 and 3 (two experiment series, not crossed) by means of spin coating at 2000 rpm for 30 seconds. Between the coatings on the two sides, the sides coated first with doping medium are in each case fixed by brief drying at 200° C. on a hotplate for two minutes. The wafer pieces are then heated on a hotplate provided with a glass-ceramic at 600° C. for in each case increasing durations. After the heating, the lifetimes of the wafers still coated with the glasses are determined by means of quasi-static photoconductivity measurement. The lifetime is read off at an injection density of 5*10¹⁴ cm⁻³. For control, some wafers are etched by means of dilute hydrofluoric acid (5%), passivated wet-chemically by means of the methanol/quinhydrone method and subjected again to a lifetime determination.

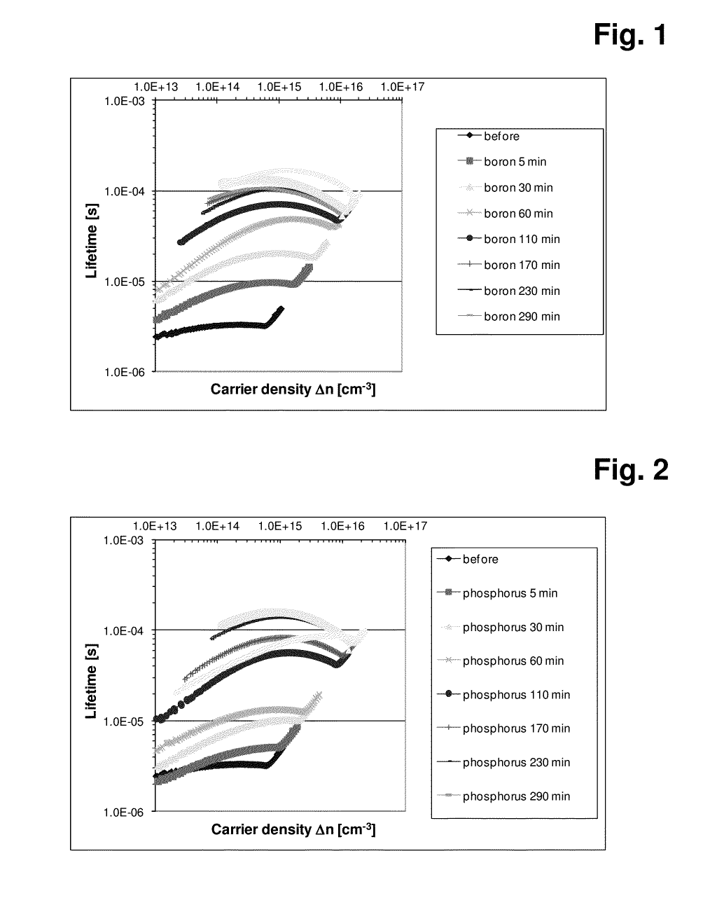

FIG. 1 shows lifetime measurements of the contaminated silicon wafer pieces, contaminated with iron and coated on both sides with boron-containing doping medium according to Claim 8. The lifetimes were recorded as a function of the heating duration at 600° C. (before=starting situation, lifetime of 3 μs). The increase in the lifetime as a function of the heating duration is clearly evident.

FIG. 2 shows lifetime measurements of the contaminated silicon wafer pieces, contaminated with iron and coated on both sides with phosphorus-containing doping medium. The lifetimes were recorded as a function of the heating duration at 600° C. (before=starting situation, lifetime of 3 μs). The increase in the lifetime as a function of the heating duration is clearly evident.

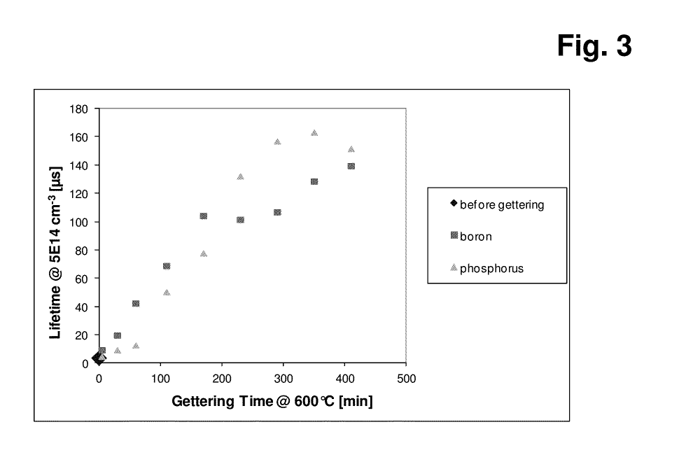

FIG. 3 shows the dependence of the lifetime of silicon wafer pieces after intentional contamination with iron, subsequent coating with getter media and subsequent heating and the exposure duration thereof at 600° C. It is clearly evident that the lifetime increases as a function of the treatment duration owing to a gettering effect of the media according to the invention.

The media according to the invention apparently exhibit a gettering effect, i.e. contaminants are removed from the volume of the silicon into the glass layer of the getter media. As a consequence, the effective lifetime of the silicon pieces increases significantly. The getter action of the media according to the invention is in this case not linked to the action of a getter diffusion, as frequently described. The gettering action is dependent on the temperature, since this influences the diffusion coefficient of iron in silicon in an exponential dependence.

### Example 2

5.8 g of ortho-phosphoric acid which has been dried in a desiccator were dissolved in 10 g of acetic anhydride by brief heating in a 250 ml round-bottomed flask. This solution is slowly added dropwise with stirring to 19.4 g of tetraethyl orthosilicate. The ethyl acetate formed is distilled off with stirring and constant warming at 100° C. In order to adjust the viscosity, a further 1-10 g of acetic anhydride can be added. In order to terminate the reaction, 25-50 g of a protic solvent (for example branched and unbranched, aliphatic, cyclic, saturated and unsaturated as well as aromatic mono-, di-, tri- and polyols (alcohols), as well as glycols, monoethers and monoacetates and the like thereof, propylene glycols, monoethers and monoacetates thereof, as well as binary, ternary, quaternary and higher mixtures of such solvents in any desired volume and/or weight mixing ratios, where the said protic solvents can be combined as desired with polar and nonpolar aprotic solvents; the term solvent is not explicitly restricted to substances which are in the liquid physical state at room temperature) are subsequently added. A ³¹P-NMR investigation of the resultant ink enables it to be clearly shown that the phosphorus species are bound into the SiO₂ network.

### Example 3

3.6 g of boric acid which has been pre-dried in a desiccator were dissolved in 12.5 g of tetrahydrofuran with stirring at 70° C. in a 250 ml round-bottomed flask. 12.3 g of acetic anhydride were added with stirring, and 19.4 g of tetraethyl orthosilicate are subsequently slowly added dropwise. When the addition of the tetraethyl orthosilicate is complete, the solution was warmed to 100° C. and freed from volatile solvents. 55 g of a protic solvent (for example branched and unbranched, aliphatic, cyclic, saturated and unsaturated as well as aromatic mono-, di-, tri- and polyols (alcohols), as well as glycols, monoethers and monoacetates and the like thereof, propylene glycols, monoethers and monoacetates thereof, as well as binary, ternary, quaternary and higher mixtures of such solvents in any desired volume and/or weight mixing ratios, where the said protic solvents can be combined as desired with polar and nonpolar aprotic solvents; the term solvent is not explicitly restricted to substances which are in the liquid physical state at room temperature) are subsequently added. The resultant mixture was refluxed until a completely clear solution had formed.

The oxide medium in the form of an ink may alternatively also be synthesised using a mixture of tetraethyl orthosilicate and aluminium triisobutoxide. The partial substitution of tetraethyl orthosilicate by aluminium triisobutoxide may make it necessary to add a substoichiometric amount of complexing ligands, such as, for example, those of acetylacetone, salicylic acid, 2,3-dihydroxy- and 3,4-dihydroxybenzoic acid or mixtures thereof.

1. Process for the production of a handling- and abrasion-resistant layer having a gettering effect on silicon wafers, characterised in that a getter medium in the form of an oxide medium
which has been prepared by
condensation and controlled gelling of symmetrically and/or asymmetrically di- to tetrasubstituted alkoxysilanes and alkoxyalkylsilanes which contain saturated or unsaturated, branched or unbranched, aliphatic, alicyclic or aromatic radicals, individually or various radicals thereof, with
a) symmetrical and asymmetrical organic and mixed organic/inorganic) carboxylic anhydrides
or with
b) strong carboxylic acids,
c) with combination of variants a) and b)
and are prepared by controlled gelling to give low- to high-viscosity oxide media is printed onto the surface of silicon wafers, and the printed-on medium is dried and compacted for vitrification in a temperature range between 50° C. and 800° C., preferably between 50° C. and 500° C., by means of one or more heating steps to be carried out sequentially (heating by means of a step function) and/or a heating ramp, and the temperature, optionally after increasing, is subsequently kept in a range from 500 to 800° C., preferably in a range from 600 to 750° C., for a few seconds to one minute, resulting in the formation of a handling- and abrasion-resistant layer having a thickness of up to 500 nm. and

2. Process according to claim 1, characterised in that the oxide media printed onto the silicon wafer surfaces exert, after drying and compaction, a gettering effect on the printed silicon without doping of the substrate and improve the lifetimes of the minority charge carriers.

3. Process according to claim 2, where silicon wafers are printed with a high-viscosity getter medium which, after thermal compaction and vitrification thereof, acts as diffusion barrier against phosphorus and boron diffusion.

4. Process according to claim 1, characterised in that use is made of getter media which are prepared using boron-containing compounds selected from the group boron oxide, boric acid and boric acid esters and/or phosphorus-containing compounds selected from the group phosphorus(V) oxide, phosphoric acid, polyphosphoric acid, phosphoric acid esters and phosphoric acid esters containing siloxane-functionalised groups in the alpha- and/or beta-position.

5. Process according to claim 4, characterised in that the vitrified layers on the surfaces release silicon-doping atoms, such as boron and/or phosphorus, to the substrate by temperature treatment at a temperature in the range between 750° C. and 1100° C., preferably between 850° C. and 1100° C., influencing the conductivity of the substrate.

6. Process according to claim 1, characterised in that, owing to the temperature treatment at temperatures in the range between 750° C. and 1100° C., preferably between 850° C. and 1100° C., of the printed substrate, the dopants are transported to depths of up to 1 μm, and electrical sheet resistivities of up to 10 Ω/sqr are produced at surface concentrations of the dopant of greater than or equal to 1*10²¹ atoms/cm³.

7. Process according to claim 1, characterised in that the concentration of parasitic doping on the treated substrates differs by at least two powers of ten from the doping of intentionally doped regions.

8. Process according to claim 1, characterised in that the getter medium is printed onto hydrophilic and/or hydrophobic silicon wafer surfaces.

9. Process according to claim 1, characterised in that the getter media are prepared using symmetrically and/or asymmetrically di- to tetrasubstituted alkoxysilanes and alkoxyalkylsilanes which contain saturated or unsaturated, branched or unbranched, aliphatic, alicyclic or aromatic radicals, individually or various of these, which may in turn be functionalised at any desired position of the alkoxide radical or alkyl radical by heteroatoms selected from the group O, N, S, Cl, Br.

10. Process according to claim 1, characterised in that the strong carboxylic acids used for the preparation of the getter media are acids from the group formic acid, acetic acid, oxalic acid, trifluoroacetic acid, mono-, di- and trichloroacetic acid, glyoxalic acid, tartaric acid, maleic acid, malonic acid, pyruvic acid, malic acid, 2-oxoglutaric acid.

11. Process according to claim 1, characterised in that the printable getter media are prepared on the basis of hybrid sols and/or gels, using alcoholates/esters, acetates, hydroxides or oxides of aluminium, germanium, zinc, tin, titanium, zirconium or lead, and mixtures thereof.

12. Process according to claim 1, characterised in that the getter medium is gelled to give a high-viscosity, approximately glass-like material, and the product obtained is either re-dissolved by addition of a suitable solvent or solvent mixture or transformed into a sol state with the aid of high-shear mixing devices and converted into a homogeneous gel by partial or complete structure recovery (gelling).

13. Process according to claim 1, characterised in that the stability is improved by the addition of “capping agents” selected from the group acetoxytrialkylsilanes, alkoxytrialkylsilanes, halotrialkylsilanes and derivatives thereof to the getter medium individually or in a mixture.

14. Process according to claim 1, characterised in that the getter medium used is formulated as high-viscosity oxide medium without addition of thickeners.

15. Getter medium in the form of a printable oxide medium, prepared in a process according to claim 1, which comprises binary or ternary systems from the group SiO₂—Al₂O₃ and/or mixtures of higher order which arise through the use of alcoholates/esters, acetates, hydroxides or oxides of aluminium, germanium, zinc, tin, titanium, zirconium or lead during the preparation.

16. Use of a printable getter medium according to claim 15 for the production of diffusion barriers in treatment processes of silicon wafers for photovoltaic, microelectronic, micromechanical and micro-optical applications.

17. Use of a getter medium according to claim 15 for the production of PERC, PERL, PERT, IBC solar cells and others, where the solar cells have further architecture features, such as MWT, EWT, selective emitter, selective front surface field, selective back surface field and bifaciality.
